(19) United States
(12) Patent Application Publication
(10) Pub. No.: US 2025/0095714 A1
(43) Pub. Date: Mar. 20, 2025

(54) WORD LINE DRIVER AND MEMORY APPARATUS

(71) Applicant: CXMT CORPORATION, Hefei (CN)

(72) Inventors: Yang ZHAO, Hefei (CN); JAEYONG CHA, Hefei (CN); SUNGJIN KIM, Hefei (CN); DONG HYUN HAN, Hefei (CN)

(21) Appl. No.: 18/963,713

(22) Filed: Nov. 28, 2024

Related U.S. Application Data
(63) Continuation of application No. PCT/CN2022/129996, filed on Nov. 4, 2022.

(30) Foreign Application Priority Data
Sep. 19, 2022 (CN) 202211138984.0

(51) Int. Cl. G11C 11/408; G11C 11/4074; H03K 19/017

(52) U.S. Cl. CPC G11C 11/4085; G11C 11/4074; H03K 19/01742

(57) ABSTRACT

Provided are a word line driver and a memory apparatus. The word line driver comprises: a first keeping transistor and a second keeping transistor; an active area, including a main portion extending in a first direction and a protruding portion adjacent to a part of the main portion and located on one side of the main portion, and the protruding portion has a first source area and a second source area; a gate, located at least above a partial area, opposite to the protruding portion, of the main portion; and a first drain area and a second drain area separately located in the main portion on two opposite sides of the gate in the first direction; where the first drain area, the gate, and the first source area constitute the first keeping transistor, while the second drain area, the gate, and the second source area constitute the second keeping transistor.

### CROSS-REFERENCES TO RELATED APPLICATIONS

This is a continuation of International Patent Application No. PCT/CN2022/129996 filed on Nov. 4, 2022, which claims priority to Chinese Patent Application No. 202211138984.0, filed on Sep. 19, 2022. The disclosure of these applications is hereby incorporated by reference in their entireties.

### BACKGROUND

A memory is a common semiconductor structure. As the size of the semiconductor structure continues to decrease, more memories may be incorporated into a chip to increase product capacity. In a dynamic random access memory (DRAM), data are required to be written into/read from memory cells by using word lines and bit lines based on a voltage applied to the word lines.

As the capacity of the DRAM increases, more memory cells are connected to a word line, and the distance between the word lines decreases, which may delay the speed. To improve the delay of word line voltage, a word line may be divided into a plurality of sub word lines and each sub word line may be driven by a sub word-line driver (SWD), where the SWD may be disposed in a word line drive circuit.

### SUMMARY

The present disclosure relates to the field of semiconductor technologies, and in particular, to a word line driver and a memory apparatus, which are at least advantageous in reducing turn-off current in a keeping transistor without increasing a layout area.

According to some embodiments of the present disclosure, one aspect of the embodiments of the present disclosure provides a word line driver, including: a first sub word-line driver, including a first keeping transistor, where the first keeping transistor is configured to provide a first preset voltage to a first word line in response to a driving signal; and a second sub word-line driver, including a second keeping transistor, where the second keeping transistor is configured to provide the first preset voltage to a second word line in response to the driving signal; where the first keeping transistor and the second keeping transistor each include: an active area, where the active area includes a main portion extending in a first direction and a protruding portion adjacent to a part of the main portion and located on one side of the main portion, and the protruding portion has a first source area and a second source area; a gate, where the gate is located at least above a partial area, opposite to the protruding portion, of the main portion; and a first drain area and a second drain area separately located in the main portion on two opposite sides of the gate in the first direction; where the first drain area, the gate, and the first source area constitute the first keeping transistor, while the second drain area, the gate, and the second source area constitute the second keeping transistor.

In some embodiments, the first source area and the second source area are the same source area.

In some embodiments, the active area further includes: a first recessed portion, where the first recessed portion is located in the main portion and recessed from a side wall, away from the protruding portion, of the main portion to the protruding portion; and the gate is further located above the first recessed portion.

In some embodiments, a bottom surface, facing the protruding portion, of the first recessed portion is located below the gate.

In some embodiments, the gate covers the entire first recessed portion, and also covers a partial area of the main portion adjacent to the first recessed portion in the first direction.

In some embodiments, the first recessed portion has two opposite end surfaces in the first direction; and in the first direction, the length of the main portion that is adjacent to one of the end surfaces and covered by the gate is a first length, the length of the main portion that is adjacent to the other end surface and covered by the gate is a second length, and the first length is equal to the second length.

In some embodiments, the gate includes a first portion and a second portion that constitute a T shape, the first portion is close to the protruding portion relative to the second portion, and the first portion serves as a transverse edge of the T shape; and the first recessed portion is located within an orthographic projection of the second portion in the active area.

In some embodiments, an orthographic projection of the gate on the active area is rectangular or H-shaped.

In some embodiments, the active area further includes: a second recessed portion, where the second recessed portion is located within the main portion and recessed away from the protruding portion from the main portion to a side wall of the protruding portion, the second recessed portion is located between the source area and the drain area, and the second recessed portion is staggered with the protruding portion in the first direction; the gate is further located above a part of the second recessed portion; and a third recessed portion, where the third recessed portion is located within the main portion and recessed away from the protruding portion from the main portion to the side wall of the protruding portion, the third recessed portion is located between the second source area and the second drain area, and the third recessed portion is staggered with the protruding portion in the first direction; and the gate is further located above a part of the third recessed portion.

In some embodiments, the protruding portion includes: a first protruding portion and a second protruding portion located on two opposite sides of the main portion separately, where the first protruding portion has the first source area, and the second protruding portion has the second source area.

In some embodiments, the first keeping transistor and the second keeping transistor constitute a keeping transistor cell; and the word line driver includes a plurality of keeping transistor cells; where two of the keeping transistor cells mirror symmetrically in a second direction, the second direction is perpendicular to the first direction, and the active areas corresponding to the two opposite keeping transistor cells in the second direction share the same protruding portion and the same source area.

In some embodiments, the first sub word-line driver further includes: a first pull-up transistor, configured to pull up the first word line to a second preset voltage in response to a first enable signal provided by a first main word line, where the second preset voltage is greater than the first preset voltage; and a first pull-down transistor, configured to pull down the first word line to the first preset voltage in response to the first enable signal provided by the first main word line; where the first pull-down transistor is disposed on a side, away from the second keeping transistor, of the first keeping transistor, and the first pull-down transistor is disposed adjacent to the first keeping transistor; the second sub word-line driver further includes: a second pull-up transistor, configured to pull up the second word line to the second preset voltage in response to a second enable signal provided by a second main word line, where the second preset voltage is greater than the first preset voltage; and a second pull-down transistor, configured to pull down the second word line to the first preset voltage in response to the second enable signal provided by the second main word line, where the second pull-down transistor is disposed on a side, away from the first keeping transistor, of the second keeping transistor, and the second pull-down transistor is disposed adjacent to the second keeping transistor.

In some embodiments, the first pull-down transistor and the first keeping transistor share the first drain area; and the second pull-down transistor and the second keeping transistor share the second drain area.

In some embodiments, both the first keeping transistor and the second keeping transistor are NMOS transistors.

According to some embodiments of the present disclosure, another aspect of the embodiments of the present disclosure provides a memory apparatus, including: a memory cell array including a plurality of memory cells, a plurality of word lines, and a plurality of bit lines, where the memory cells are connected to the corresponding word lines and the corresponding bit lines; and the word line driver provided by any of the foregoing embodiments.

Technical solutions provided in the embodiments of the present disclosure have at least the following advantages:

The word line driver provided in the embodiments of the present disclosure includes a first sub word-line driver with a first keeping transistor and a second sub word-line driver with a second keeping transistor, where a length direction of a channel area between the first source area and first drain area of the first keeping transistor tilts relative to an extension direction of the active area, which can increase the length of the channel area of the first keeping transistor without increasing the layout area, thereby reducing turn-off current in the first keeping transistor and then ensuring that the first word line can be completely turned off, that is, the first word line can be thoroughly pulled down to the first preset voltage by using the first keeping transistor. Similarly, a length direction of a channel area between the second source area and second drain area of the second keeping transistor tilts relative to the extension direction of the active area, which can increase the length of the channel area of the second keeping transistor without increasing the layout area, thereby reducing turn-off current in the second keeping transistor and then ensuring that the second word line can be completely turned off, that is, the second word line can be thoroughly pulled down to the first preset voltage by using the second keeping transistor.

### BRIEF DESCRIPTION OF THE DRAWINGS

One or more embodiments are illustrated through corresponding drawings, and these illustrations do not constitute limitations on the embodiments. Elements with the same reference numerals in the drawings are represented as similar elements. Unless otherwise stated, the drawings are not limited proportionally. In order to describe the technical solutions in the embodiments of the present disclosure or in the conventional technologies more clearly, the drawings to be used in the embodiments will be introduced simply. Apparently, the drawings described below are merely some embodiments of the present disclosure. Those of ordinary skill in the art may obtain other drawings according to these drawings without any creative efforts.

FIG. 1 is a schematic diagram of a layout structure of a word line driver;

FIG. 2 is a schematic diagram of a circuit structure of a word line driver provided in an embodiment of the present disclosure;

FIGS. 3 to 8 are schematic diagrams of many different layout structures of a word line driver provided in embodiments of the present disclosure;

FIG. 9 is another schematic diagram of a circuit structure of a word line driver provided in an embodiment of the present disclosure; and

FIG. 10 is a schematic diagram of a layout structure of the word line driver corresponding to FIG. 9.

### DETAILED DESCRIPTION

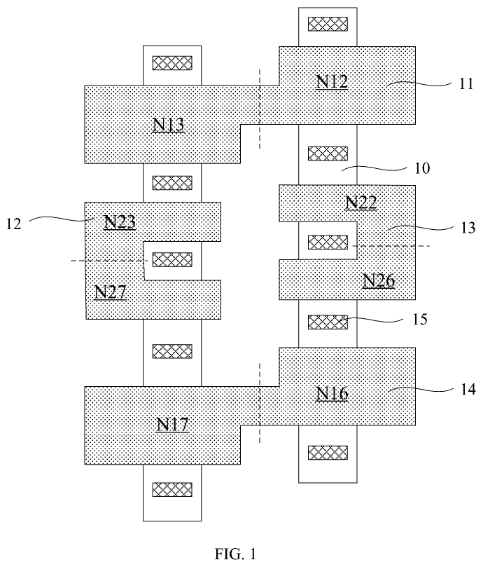

A word line driver includes a plurality of sub word-line drivers, and each of the sub word-line drivers includes a pull-down transistor and a keeping transistor. FIG. 1 is a schematic diagram of a layout structure of a word line driver. With reference to FIG. 1, the word line driver includes a plurality of discrete active areas 101, and each of the active areas 101 is used for defining a plurality of pull-down transistors and a plurality of keeping transistors, where the plurality of pull-down transistors are marked by N12, N13, N16, and N17, and the plurality of keeping transistors are marked by N23, N22, N26, and N27; and N13 and N23 constitute a sub word-line driver, N17 and N27 constitute a sub word-line driver, N12 and N22 constitute a sub word-line driver, and N16 and N26 constitute a sub word-line driver. N12 and N13 share a first gate 11 and belong to different active areas 101, N23 and N27 belong to the same active area 10 and share a second gate 12, N22 and N26 belong to the same active area 101 and share a third gate 13, and N16 and N17 belong to different active areas 101 and share a fourth gate 14; and a plurality of conductive plugs 15 is further included, each of the conductive plugs 15 is electrically connected to a source or drain of the pull-down transistor and a source or drain of the keeping transistor.

A channel length of the keeping transistor is determined by a length of the corresponding gate in an extension direction of the active area. To reduce turn-off current in the keeping transistor, the channel length may be increased and the length of the corresponding gate in the extension direction of the active area 101 may be increased. However, the area occupied by the gate in the layout also increases accordingly. As a result, an area in the layout where the conductive plug 15 may be designed will be reduced, and requirements for a lithography process for forming the conductive plug 15 are higher. In particular, the smaller area enclosed by the gate 12 will increase the process difficulty of forming the conductive plug 15 within the area enclosed by the second gate 12. In addition, this method will also be limited by process limits.

The embodiments of the present disclosure will be described in detail below with reference to the accompanying drawings. Those of ordinary skill in the art may understand that, in the embodiments of the present disclosure, many technical details are provided for readers to understand the present disclosure better. However, the technical solutions of the present disclosure may still be implemented even without these technical details and various changes and modifications in the following embodiments.

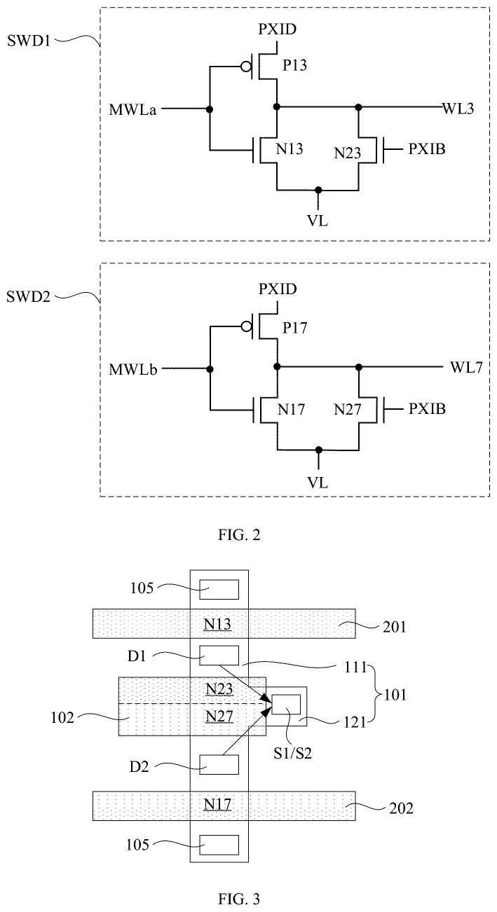

FIG. 2 is a schematic diagram of a circuit structure of a word line driver provided in an embodiment of the present disclosure, and FIGS. 3 to 8 are schematic diagrams of many different layout structures of a word line driver provided in embodiments of the present disclosure.

With reference to FIGS. 2 to 8, the word line driver provided in the embodiments of the present disclosure includes: a first sub word-line driver SWD1, including a first keeping transistor N23, where the first keeping transistor N23 is configured to provide a first preset voltage VL to a first word line WL3 in response to a driving signal; and a second sub word-line driver SWD2, including a second keeping transistor N27, where the second keeping transistor is configured to provide the first preset voltage VL to a second word line WL7 in response to the driving signal PXID; where the first keeping transistor N23 and the second keeping transistor N27 each include: an active area 101, where the active area 101 includes a main portion 111 extending in a first direction X and a protruding portion 121 adjacent to a part of the main portion 111 and located on one side of the main portion 111, and the protruding portion 121 has a first source area S1 and a second source area S2; a gate 102, where the gate 102 is located at least above a partial area, opposite to the protruding portion 121, of the main portion 111; and a first drain area D1 and a second drain area D2 separately located in the main portion 111 on two opposite sides of the gate 102 in the first direction; where the first drain area D1, the gate 102, and the first source area S1 constitute the first keeping transistor N23, while the second drain area D2, the gate 102, and the second source area S2 constitute the second keeping transistor N27.

In the foregoing embodiment, the first source area S1 of the first keeping transistor N23 is located on the protruding portion 121, the protruding portion 121 is located on an outer side of the main portion 111 extending in the first direction X, that is, the first drain area D1 and the first source area S1 are not arranged in the first direction X, and compared with a solution in which the first drain area and the first source area are located on two opposite sides of the gate in the first direction, a direction from the first source area S1 to the first drain area D1 tilts relative to the first direction X in the foregoing embodiment, so that the first keeping transistor N23 has a larger channel length, which is beneficial to reducing turn-off current in the first keeping transistor N23 and enables the first word line to be completely turned off. Similarly, a direction from the second source area S2 to the second drain area D2 also tilts relative to the first direction X in the foregoing embodiment, so that the second keeping transistor N27 also has a larger channel length, which is beneficial to reducing turn-off current in the second keeping transistor N27.

The word line driver provided in the embodiments of the present disclosure will be described in more details below with reference to the drawings.

The active area 101 is an AA area, commonly referred to as an Active Area. The first source area S1 and the first drain area D1 are used for defining a source and a drain of the first keeping transistor N23 separately; and the second source area S2 and the second drain area D2 are used for defining a source and a drain of the second keeping transistor N27 separately.

The first keeping transistor N23 has an effect of ensuring that voltage in the first word line WL3 is pulled down to the first preset voltage VL after the first word line WL3 changes from a selected state (namely, activated state) to an unselected state (namely, closed state), thereby avoiding a problem that the first word line WL3 cannot be completely closed due to interference such as noise. The second keeping transistor N27 has an effect of ensuring that voltage in the second word line WL7 is pulled down to the first preset voltage VL after the second word line WL7 changes from a selected state to an unselected state, thereby avoiding a problem that the second word line WL7 cannot be completely closed due to interference such as noise.

Both the first source area S1 and the second source area S2 are connected to a preset power supply, and a level of the preset power supply is the first preset voltage, or a level of the preset power supply is equivalent to the first preset voltage VL. It may be understood that “equivalent” refers to a difference between the level of the preset power supply and the first preset voltage VL within an allowable range, and the levels of the two may be considered as the same within this allowable range. That is, in a circuit corresponding to the word line driver, the first source area S1 and the second source area S2 may be considered as nodes having the same potential, namely, the first source area S1 and the second source area S2 are electrically connected.

In some embodiments, with reference to FIG. 3, the first source area S1 and the second source area S2 may be the same source area, that is, the first source area S1 and the second source area S2 are located in the same protruding portion 121 and are the same source area, which is marked by S1/S2 in FIG. 3. On the one hand, the layout area can be saved, and the area of the word line driver can be reduced. On the other hand, the first source area S1 and the second source area S2 can be electrically connected, and a contact structure and a metal layer are not required to achieve the electrical connection, thereby reducing manufacturing difficulties of the word line driver and saving manufacturing costs. Solid lines with arrows in FIG. 3 indicate a channel length direction of the first keeping transistor and a channel length direction of the second keeping transistor. Correspondingly, a contact structure (LiCon, local interconnect contact) may be disposed in the same source area to serve as a source leading-out end.

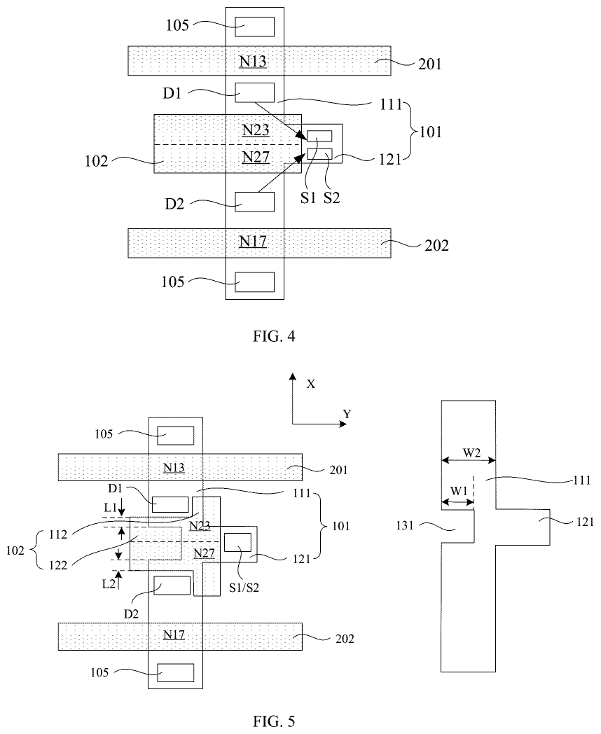

In other embodiments, with reference to FIG. 4, the first source area S1 and the second source area S2 may be located in the same protruding portion 121, and the first source area S1 and the second source area S2 may be separated from each other. Such settings have the following advantages: the first source area S1 and the second source area S2 are separated from each other, and doping concentrations of the first source area S1 and the second source area S2 may be different to meet respective electrical requirements of the first keeping transistor N23 and the second keeping transistor N27, where the doping concentration refers to a doping concentration of N-type ions or P-type ions; in addition, the first keeping transistor N23 has a first channel, and the second keeping transistor N27 has a second channel; and because the first source area S1 and the second source area S2 are separated from each other, the first channel and the second channel may be independent of each other, which is beneficial to increasing sizes of the first channel and the second channel and reducing carrier crowding effects of the first drain area D1 and the second drain area D2. In a specific example, both the first keeping transistor N23 and the second keeping transistor N27 may be NMOS transistors, and the doping concentration refers to a doping concentration of N-type ions. It may be understood that the first source area S1 and the second source area S2 may be electrically connected by configuring a contact structure above each of the first source area S1 and the second source area S2 and a metal layer electrically connected to the two contact structures. Solid lines with arrows in FIG. 4 indicate a channel length direction of the first keeping transistor and a channel length direction of the second keeping transistor.

FIG. 5 shows schematic structural diagrams of a layout of a word line driver and an active area. In FIG. 5, the left shows a schematic structural diagram of a layout of a word line driver, and the right shows a schematic structural diagram of an active area on the left. With reference to FIG. 5, in some embodiments, the active area 101 may further include a first recessed portion 131, where the first recessed portion 131 is located in the main portion 111 and recessed from a side wall, away from the protruding portion 121, of the main portion 111 to the protruding portion 121. The first recessed portion 131 is configured to reduce the conduction area between the first drain area D1 and the second drain area D2, thereby suppressing electric leakage between the first drain area D1 and the second drain area D2. In addition, the first drain area D1 may be electrically connected to the first word line WL3, the second drain area D2 may be electrically connected to the second word line WL7, and the first recessed portion 131 can reduce electric leakage between the first word line WL3 and the second word line WL7. It may be understood that the word line driver may further include an isolation structure, and the isolation structure is filled in the first recessed portion 131.

Moreover, in some embodiments, the gate 102 may further be located above the first recessed portion 131, which is beneficial to increasing the volume of the gate 102 and reducing the resistance of the gate 102.

The first recessed portion 131 may be recessed in a square or arc shape. In some embodiments, in a direction perpendicular to the first direction X1, a maximum depression depth of the first recessed portion 131 is defined as a first width W1, and a maximum width of the main portion 111 is defined as a second width W2. To ensure that the first recessed portion 131 has enough ability to suppress the electric leakage between the first drain area D1 and the second drain area D2, the first keeping transistor N23 and the second keeping transistor N27 have relatively high saturation current Idast, and the first keeping transistor N23 and the second keeping transistor N27 have relatively low turn-off current Ioff. A ratio of the first width W1 to the second width W2 is within a range of 0.3-0.7. In a specific example, the ratio of the first width W1 to the second width W2 is within a range of 0.4-0.6, such as 0.45, 0.5, or 0.55, which is beneficial to further ensuring the relatively low turn-off current Ioff on the premise of the relatively high saturation current.

In some embodiments, the gate 102 may cover the entire first recessed portion 131, and also cover a partial area of the main portion 111 adjacent to the first recessed portion 131 in the first direction X. That is, the first recessed portion 131 completely falls into an area covered by the gate 102. On the one hand, the area covered by the gate 102 is relatively large, so that the gate 102 has a relatively large volume, which is beneficial to reducing the resistance of the gate 102. On the other hand, the gate 102 covers the entire first recessed portion 131. On the premise of this position relationship, the gate 102 further covers a part of the main portion 111 adjacent to the first recessed portion 131, so that both the first keeping transistor N23 and the second keeping transistor N27 have relatively large sizes, that is, the first keeping transistor and the second keeping transistor occupy a relatively large active area, which improves the saturation current. Moreover, the gate 102 covers the entire first recessed portion 131, so that the process for forming the gate 102 has a relatively large process window, which reduces difficulties of the process for forming the gate 102.

In some embodiments, the first recessed portion 131 may be full of the isolation structure. In other embodiments, the gate 102 may cover a bottom surface and side walls of the first recessed portion 131. In this case, the bottom surface and side walls, covered by the gate 102, of the first recessed portion 131 also serve as a part of a channel. This can increase the area of the channel controlled by the gate 102 to improve the ability of the gate 102 to control channel conduction. Moreover, because a gate conductive layer in the gate 102 is correspondingly located within the first recessed portion 131, which can increase the volume of the gate 102 and further reduce the resistance of the gate 120. It may be understood that the channel includes the first channel corresponding to the first keeping transistor N23 and the second channel corresponding to the second keeping transistor N27. The gate 102 includes a gate dielectric layer and a gate electrode layer located on a surface of the gate dielectric layer. The gate 102 covers a bottom surface and side walls of the first recessed portion 131, indicating that the gate dielectric layer is located on the bottom surface and side walls of the first recessed portion 131 and the gate conductive layer is further located within the first recessed portion 131.

In a specific example, the gate 102 may cover a part of the bottom surface and a part of the side walls, and correspondingly, an isolation structure may be filled below the gate 102 in the first recessed portion 131. In another specific example, the gate 102 may cover all the bottom surface and all the top surface,

In other embodiments, the gate 102 may alternatively cover only a partial area of the first recessed portion 131, for example, a partial area, facing the protruding portion 121, of the first recessed portion 131 is covered by the gate 102, while the remained area, away from the protruding portion 121, of the first recessed portion 131 is not covered by the gate 102. Alternatively, the gate 102 and the first recessed portion 131 may be completely staggered.

In some embodiments, the bottom surface, facing the protruding portion 121, of the first recessed portion 131 may be located below the gate 102. In other embodiments, the bottom surface, facing the protruding portion 121, of the first recessed portion 131 may alternatively be flush with a side surface, away from the protruding portion 121, of the gate 102.

In addition, the first recessed portion 131 may have two opposite end surfaces in the first direction X; and in the first direction X, the length of the main portion 111 that is adjacent to one of the end surfaces and covered by the gate 102 is a first length L1, the length of the main portion 111 that is adjacent to the other end surface and covered by the gate 102 is a second length L2, and the first length L1 may be equal to the second length L2. That is, in the first direction X, the first recessed portion 131 is located in the middle of the gate 102, which is beneficial to improving symmetry of the first keeping transistor N23 and the second keeping transistor N27 and reducing the mismatch of different transistors.

It may be understood that, in other embodiments, the first length L1 may alternatively be different from the second length L2, for example, the first length L1 may be less than or greater than the second length L1.

In some embodiments, with reference to FIG. 4, the gate 102 may include a first portion 112 and a second portion 122 that constitute a T shape, the first portion 112 is close to the protruding portion 121 relative to the second portion 122, and the first portion 112 serves as a transverse edge of the T shape. That is, the first portion 112 serves as “-” of the T shape, and the second portion 122 serves as “|” of the T shape. The T-shaped gate 102 increases the volume of the gate 102 to reduce the resistance of the gate 102, and the “|” may reserve spatial positions for forming contact structures on two opposite sides in the first direction X, where one contact structure is used for electrical connection with the first drain area D1, and the other contact structure is used for electrical connection with the second drain area D2.

The first recessed portion 131 may be located within an orthographic projection of the second portion 122 in the active area 101. In addition, the first recessed portion 131 may have two opposite end surfaces in the first direction; and in the first direction X, the length of the main portion 111 that is adjacent to one of the end surfaces and covered by the second portion 122 is a first length L1, the length of the main portion 111 that is adjacent to the other end surface and covered by the second portion 122 is a second length L2, and the first length L1 may be equal to the second length L2.

In other embodiments, an orthographic projection of the gate 102 on the active area 101 may be rectangular or H-shaped. In a specific example, the H-shaped gate 102 includes two opposite crossbeams and a connecting portion located between the crossbeams, where the two crossbeams are arranged in the first direction X, and the first recessed portion 131 may alternatively be located below the connecting portion.

FIG. 6 is another schematic diagram of a layout structure of a word line driver. With reference to FIG. 6, the active area 101 may further include: a second recessed portion 141, where the second recessed portion 141 is located within the main portion 111, recessed away from the protruding portion 121 from the main portion 111 to a side wall of the protruding portion 121, and located between the first drain area D1 and the protruding portion 121, and the second recessed portion 141 is staggered with the protruding portion 121 in the first direction X. The second recessed portion 141 may be located between the first source area S1 and the first drain area D1.

The second recessed portion 141 is configured to further increase the length of the channel area in the first keeping transistor N23 and further reduce the turn-off current in the first keeping transistor N23.

With continued reference to FIG. 6, the active area 101 may further include: a third recessed portion 151, where the third recessed portion 151 is located within the main portion 111, recessed away from the protruding portion 121 from the main portion 111 to the side wall of the protruding portion 121, and located between the second drain area D2 and the protruding portion 121, and the third recessed portion 151 is staggered with the protruding portion 121 in the first direction X. The third recessed portion 151 may alternatively be located between the second source area S2 and the second drain area D2.

The third recessed portion 151 is configured to further increase the length of the channel area in the second keeping transistor N27 and further reduce the turn-off current in the second keeping transistor N27.

With continued reference to FIG. 6, the gate 102 may alternatively be located above the second recessed portion 141, and the gate 102 may alternatively be located above a part of the third recessed portion 151. In this case, the volume of the gate 102 can be further increased and the resistance of the gate 102 can be further reduced.

Understandably, in a specific example, the active area 101 may include any one or more of the first recessed portion 131, the second recessed portion 141, or the third recessed portion 151.

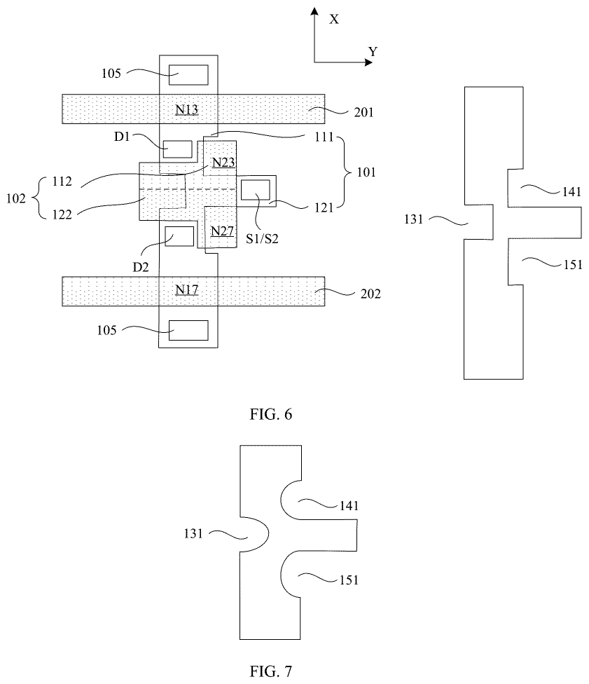

FIG. 7 is a schematic structural diagram of an active area 101 including a first recessed portion 131, a second recessed portion 141, and a third recessed portion 151. With reference to FIG. 7, in some embodiments, at least one of the first recessed portion 131, the second recessed portion 141, and the third recessed portion 151 may be recessed in an arc shape, which can achieve corner rounding to avoid problems such as corner tip discharge.

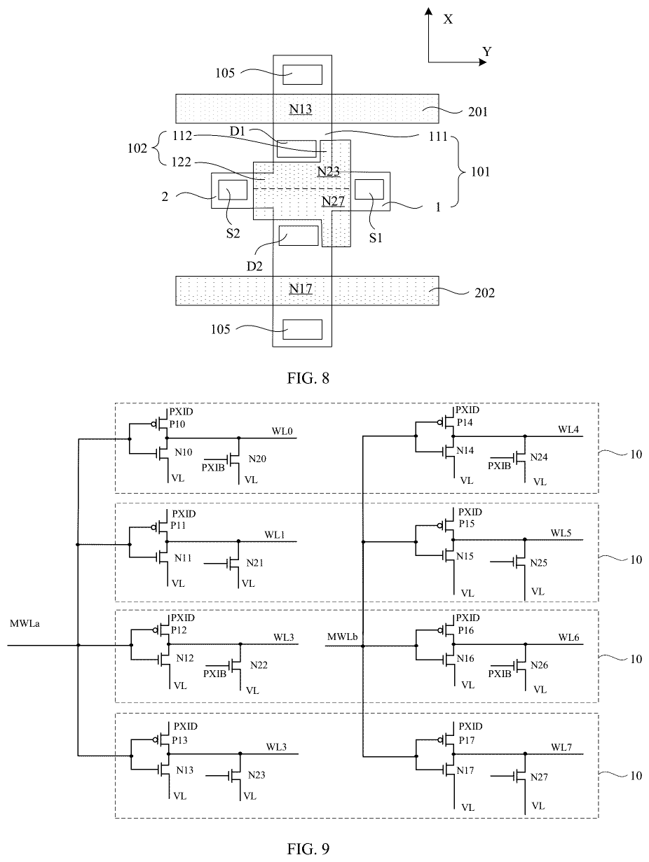

FIG. 8 is another schematic diagram of a layout structure of a word line driver. With reference to FIG. 8, in some embodiments, the protruding portion 121 may further include: a first protruding portion 1 and a second protruding portion 2 located on two opposite sides of the main portion 111 separately, where the first protruding portion 1 has the first source area S1, and the second protruding portion 2 has the second source area S2. That is, the first source area S1 and the second source area S2 are located within different protruding portions 121, which can provide large process windows for forming the first source area S1 and the second source area S2, and increase the area of the first source area S1 and the second source area S2, thereby reducing the contact resistance of the first source area S1 and the second source area S2.

Correspondingly, with reference to FIG. 8, the active area 101 may include two second recessed portions 141 and two third recessed portions 151, one of the first recessed portions 141 is located between the first drain area D1 and the first protruding portion 1, the other first recessed portion 141 is located between the first drain area D1 and the second protruding portion 2, one of the third recessed portions 151 is located between the second drain area D1 and the first protruding portion 1, and the other third recessed portion 151 is located between the second drain area D2 and the second protruding portion 2.

With reference to FIGS. 2 to 7, the first sub word-line driver SWD1 may further include: a first pull-up transistor P13, configured to pull up the first word line WL3 to a second preset voltage PXID in response to a first enable signal provided by a first main word line MWLa, where the second preset voltage PXID is greater than the first preset voltage VL; and a first pull-down transistor N13, configured to pull down the first word line WL3 to the first preset voltage VL in response to the first enable signal provided by the first main word line MWLa. The second sub word-line driver SWD2 further includes: a second pull-up transistor P17, configured to pull up the second word line WL7 to the second preset voltage PXID in response to a second enable signal provided by a second main word line MWLb, where the second preset voltage PXID is greater than the first preset voltage VL; and a second pull-down transistor N17, configured to pull down the second word line WL7 to the first preset voltage VL in response to the second enable signal provided by the second main word line MWLb. Correspondingly, the word line driver further includes: a first pull-down gate 201, which serves as a gate of the first pull-down transistor N13; and a second pull-down gate 202, which serves as a gate of the second pull-down transistor N17. Extension directions of both the first pull-down gate 201 and the second pull-down gate 202 are perpendicular to the first direction X.

The working principle of the first sub word-line driver SWD1 as an example will be explained below.

The first enable signal includes a first state and a second state, and a level of the first state is different from that of the second state; when the first enable signal is in the first state, the first sub word-line driver SWD1 receives a valid driving signal, the first pull-up transistor P13 is turned on, the first sub line WL3 is pulled up to the second preset voltage PXID, and the second preset voltage PXID is the same as or equivalent to a voltage of the driving signal; and when the first enable signal is in the second state, the first pull-down transistor N13 is turned on, the first word line WL3 is pulled down to the first preset voltage VL, and the first keeping transistor N23 is turned on, thereby further ensuring that the first word line WL3 is pulled down to the first preset voltage VL and avoiding interference of signal noise to the first word line WL3.

The working principle of the second sub word-line driver may be referenced to the working principle of the first sub word-line driver, and will not be repeated here. In a specific example, both the first pull-up transistor P13 and the second pull-up transistor P17 may be PMOS transistors, and both the first pull-down transistor N13 and the second pull-down transistor N17 may be NMOS transistors. Both the first keeping transistor N23 and the second keeping transistor N27 may be NMOS transistors.

With reference to FIG. 3, in some embodiments, the first pull-down transistor N13 may be disposed on a side, away from the second keeping transistor N27, of the first keeping transistor N23, and the first pull-down transistor N13 may be disposed adjacent to the first keeping transistor N23. The second pull-down transistor N17 may be disposed on a side, away from the first keeping transistor N23, of the second keeping transistor N27, and the second pull-down transistor N17 may be disposed adjacent to the second keeping transistor N27.

It should be noted that, for the convenience of illustration and explanation, the channel areas of the transistors corresponding to the active area are marked by N13, N23, P13, N17, N27, and P17 in FIG. 3.

The first pull-down transistor N13 and the first keeping transistor N23 may share the first drain area D1. By sharing the first drain area D1, a drain of the first pull-down transistor and the drain of the first keeping transistor are electrically connected without additional contact structures and metal layers, which reduces complexity of the layout structure. The second pull-down transistor N17 and the second keeping transistor N27 may share the second drain area D2. By sharing the second drain area D2, a drain of the second pull-down transistor and the drain of the second keeping transistor are electrically connected without additional contact structures and metal layers, which reduces complexity of the layout structure.

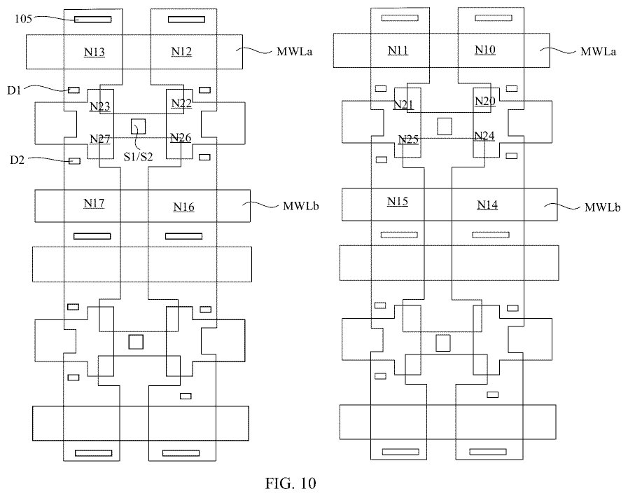

FIG. 9 is another schematic diagram of a circuit structure of a word line driver provided in an embodiment of the present disclosure, and FIG. 10 is a schematic diagram of a layout structure of the word line driver corresponding to FIG. 9. With reference to FIGS. 9 and 10, in some embodiments, the first keeping transistor N23 and the second keeping transistor N27 constitute a keeping transistor cell 10, and the word line driver includes a plurality of keeping transistor cells 10, where two transistor cells 10 are mirrored opposite in a second direction Y, and the second direction Y is perpendicular to the first direction X.

It should be noted that, for the convenience of illustration and explanation, in FIGS. 9 and 10, first keeping transistors in different keeping transistor cells 10 are marked by different reference numerals, including N20, N21, N22, and N23, and first word lines connected to the different first keeping transistors are marked by WL0, WL1, WL2, and WL3, respectively; second keeping transistors in the different keeping transistor cells 10 are marked by different reference numerals, including N24, N25, N26, and N27, and second word lines connected to the different second keeping transistors are marked by WL4, WL5, WL6, and WL7, respectively; different first pull-down transistors are marked by N10, N11, N12, and N13, respectively; different second pull-down transistors are marked by N14, N15, N16, and N17, respectively; different first pull-up transistors are marked by P10, P11, P12, and P13, respectively; and different second pull-up transistors are marked by P14, P15, P16, and P17, respectively.

In some embodiments, with reference to FIG. 10, active areas 101 corresponding to two opposite keeping transistor cells 10 in the second direction Y share the same protruding portion 121, and the two opposite keeping transistor cells 10 in the second direction Y may also share the same source area. For example, the first keeping transistors N23/N22 and the second keeping transistors N27/N26 in the two keeping transistor cells 10 may share the same active area, that is, the four keeping transistors may share the same active area, and the active area is located on the same protruding portion 121. This further saves the layout area and reduces the complexity of the layout structure.

In other embodiments, the two first keeping transistors in the two keeping transistor cells 10 may share the same source area located in the same protruding portion 121, and the two second keeping transistors do not share the source area with the first keeping transistors. Alternatively, the two second keeping transistors of the two keeping transistor cells 10 may share the same source area located in the same protruding portion 121, and the two first keeping transistors do not share the same source area with the second keeping transistors.

The word line driver may further include: a plurality of contact structures 105, where each of the contact structures 105 is used for electrical connection with the corresponding first source area S1, second source area S2, first drain area D1, or second drain area D2, and also for electrical connection with the source or drain area of the first pull-down transistor, second pull-down transistor, first pull-up transistor, or second pull-up transistor.

According to the word line driver provided in the foregoing embodiment, channel length directions of two keeping transistors are designed to tilt relative to the extension direction of the active area 101, which can increase channel lengths of the keeping transistors without increasing the layout area, thereby reducing turn-off current in the keeping transistors and improving the ability of the keeping transistors to turn off the word lines connected to the keeping transistors. Moreover, the channel length directions tilt relative to the extension direction of the active area 101, which can also reserve more space for laying the contact structures 105 and improve spatial utilization of the layout.

Correspondingly, an embodiment of the present disclosure further provides a memory apparatus, including the word line driver provided by the foregoing embodiments. The memory apparatus provided by the embodiment of the present disclosure will be explained in detail below. For the same or corresponding parts as the foregoing embodiments, reference may be made to the detailed explanation of the foregoing embodiments, and details will not be repeated below.

The memory apparatus provided by the embodiment of the present disclosure includes: a memory cell array including a plurality of memory cells, a plurality of word lines, and a plurality of bit lines, where the memory cells are connected to the corresponding word lines and the corresponding bit lines; and the word line driver provided by the foregoing embodiments.

Each sub word-line driver in the word line driver is electrically connected to a corresponding word line to select/activate the corresponding word line or close the corresponding word line.

The memory apparatus may be a DRAM system, such as a DDR5 DRAM system or a DDR4 DRAM system. In other embodiments, the memory apparatus may alternatively be an SRAM system, an SDRAM system, an ROM system, or a flash memory system.

Those of ordinary skill in the art may understand that the foregoing implementations are specific embodiments for implementing the present disclosure, and in actual applications, various changes may be made in form and details without departing from the spirit and scope of the present disclosure. Any person skilled in the art may make various changes and modifications without departing from the spirit and scope of the present disclosure. Therefore, the protection scope of the present disclosure shall be subject to the scope of the claims.

What is claimed is:

1. A word line driver, comprising:
a first sub word-line driver, comprising a first keeping transistor, wherein the first keeping transistor is configured to provide a first preset voltage to a first word line in response to a driving signal; and
a second sub word-line driver, comprising a second keeping transistor, wherein the second keeping transistor is configured to provide the first preset voltage to a second word line in response to the driving signal, wherein the first keeping transistor and the second keeping transistor comprise:
an active area, wherein the active area comprises a main portion extending in a first direction and a protruding portion adjacent to a part of the main portion and located on one side of the main portion, and the protruding portion has a first source area and a second source area;
a gate, wherein the gate is located at least above a partial area, opposite to the protruding portion, of the main portion; and
a first drain area and a second drain area separately located in the main portion on two opposite sides of the gate in the first direction; and, wherein
the gate comprises a first portion and a second portion arranged along a second direction, the second portion being farther from the protruding portion relative to the first portion, the second direction being perpendicular to the first direction;
the active area further comprises: a first recessed portion, located in the main portion and recessed from a side wall, away from the protruding portion, of the main portion to the protruding portion; and
the second portion overlays at least a part of the first recessed portion, and a orthographic projection of the second portion in the first direction is contained within a orthographic projection of the first portion in the first direction, with an edge of the orthographic projection of the second portion in the first direction not coinciding with the edge of the orthographic projection of the first portion in the first direction, thereby reserving positions for forming a first drain area contact structure and a second drain area contact structure, where the first drain area contact structure is used for electrical connection with the first drain area; the second drain area contact structure is used for electrical connection with the second drain area; wherein the first drain area, the gate, and the first source area constitute the first keeping transistor, while the second drain area, the gate, and the second source area constitute the second keeping transistor.

2. The word line driver according to claim 1, wherein the gate is composed of the first portion and the second portion.

3. The word line driver according to claim 1, wherein the gate covers only a partial area of the first recessed portion facing the protruding portion, and does not cover the remaining part of the first recessed portion that is away from the protruding portion.

4. The word line driver according to claim 1, wherein the first source area and the second source area are the same source area.

5. The word line driver according to claim 1, wherein a bottom surface, facing the protruding portion, of the first recessed portion is located below the gate.

6. The word line driver according to claim 1, wherein the gate covers an entire first recessed portion, and also covers a partial area of the main portion adjacent to the first recessed portion in the first direction.

7. The word line driver according to claim 6, wherein the first recessed portion has two opposite end surfaces in the first direction; and in the first direction, a length of the main portion that is adjacent to one of the end surfaces and covered by the gate is a first length, the length of the main portion that is adjacent to the other end surface and covered by the gate is a second length, and the first length is equal to the second length.

8. The word line driver according to claim 1, wherein the gate comprises a first portion and a second portion that constitute a T shape, wherein the first portion is close to the protruding portion relative to the second portion; and the first recessed portion is located within an orthographic projection of the second portion in the active area.

9. The word line driver according to claim 1, wherein the active area further comprises:
a second recessed portion, wherein the second recessed portion is located within the main portion and recessed away from the protruding portion from the main portion to a side wall of the protruding portion, the second recessed portion is located between the source area and the drain area, and the second recessed portion is staggered with the protruding portion in the first direction; the gate is further located above a part of the second recessed portion; and
a third recessed portion, wherein the third recessed portion is located within the main portion and recessed away from the protruding portion from the main portion to the side wall of the protruding portion, the third recessed portion is located between the second source area and the second drain area, and the third recessed portion is staggered with the protruding portion in the first direction; the gate is further located above a part of the third recessed portion.

10. The word line driver according to claim 1, wherein the first keeping transistor and the second keeping transistor constitute a keeping transistor cell; and the word line driver comprises a plurality of keeping transistor cells;
wherein two of the keeping transistor cells mirror symmetrically in a second direction, and the active areas corresponding to the two opposite keeping transistor cells in the second direction share the same protruding portion and the same source area.

11. The word line driver according to claim 1, wherein the first sub word-line driver further comprises:
a first pull-up transistor, configured to pull up the first word line to a second preset voltage in response to a first enable signal provided by a first main word line, wherein the second preset voltage is greater than the first preset voltage; and
a first pull-down transistor, configured to pull down the first word line to the first preset voltage in response to the first enable signal provided by the first main word line;
wherein the first pull-down transistor is disposed on a side, away from the second keeping transistor, of the first keeping transistor, and the first pull-down transistor is disposed adjacent to the first keeping transistor;
the second sub word-line driver further comprises:
a second pull-up transistor, configured to pull up the second word line to the second preset voltage in response to a second enable signal provided by a second main word line, wherein the second preset voltage is greater than the first preset voltage; and
a second pull-down transistor, configured to pull down the second word line to the first preset voltage in response to the second enable signal provided by the second main word line, wherein the second pull-down transistor is disposed on a side, away from the first keeping transistor, of the second keeping transistor, and the second pull-down transistor is disposed adjacent to the second keeping transistor.

12. The word line driver according to claim 11, wherein the first pull-down transistor and the first keeping transistor share the first drain area; and the second pull-down transistor and the second keeping transistor share the second drain area.

13. The word line driver according to claim 1, wherein both the first keeping transistor and the second keeping transistor are NMOS transistors.

14. A memory apparatus, comprising:
a memory cell array comprising a plurality of memory cells, a plurality of word lines, and a plurality of bit lines, wherein the memory cells are connected to the corresponding word lines and the corresponding bit lines; and
the word line driver according to claim 1.
